(19) United States
(12) Patent Application Publication
(10) Pub. No.: US 2026/0367194 A1
(43) Pub. Date: Nov. 19, 2026

(54) Spatially Integrating Magnetometer

(71) Applicant: Christopher M. Rey, Powell, TN (US)

(72) Inventor: Christopher M. Rey, Powell, TN (US)

(21) Appl. No.: 18/631,517

(22) Filed: Apr. 10, 2024

Related U.S. Application Data
(60) Provisional application No. 63/540,485, filed on Sep. 26, 2023.

(51) Int. Cl. G01R 33/032; G01R 33/02; G01R 33/04

(52) U.S. Cl. CPC G01R 33/032; G01R 33/0206; G01R 33/04

(57) ABSTRACT

A scanning spatially integrating magnetometer, having a drive motor and a guide mechanically coupled to the drive motor. A carriage is mechanically coupled to the guide, and the drive motor is adapted to provide motive power to translate the carriage along the guide. A B-field sensor is mechanically coupled to the carriage. A controller is in signal communication with the drive motor and the B-field sensor, and is adapted to receive signals from the B-field sensor and calculate an integrated B-field as the B-field sensor translates along the guide.

### PRIORITY

This application claims priority on prior pending U.S. provisional patent application Ser. No. 63/540,485 filed 2023 Sep. 26, the entirety of the disclosure of which is incorporated herein.

### GOVERNMENT RIGHTS

This invention was made with government support under SBIR contract N68335-21-C-0313 awarded by the United States Department of Navy. The government has certain rights in the invention.

### FIELD

This invention relates to the field of magnetic measurements and magnetic measurement sensors. More particularly, this invention relates to magnetic measurements performed over a finite distance in space and how to measure the integrated magnetic field and integrated magnetic field gradient over that finite distance.

### INTRODUCTION

Magnetic measurements are useful in a wide variety of applications including, for example, Magnetic Resonance Imaging (MRI), Nuclear Magnetic Resonance (NMR), accelerator magnets for High Energy Physics (HEP) and Nuclear Physics (NP), and magnets for fusion energy.

There are a plethora of types of magnetic measurement sensors (also known as magnetometers). Magnetic field sensors come in a wide variety of types including but not limited to Flux Gate Magnetometers (FGM), NMR sensors, Hall sensors, Giant Magneto-Resistance (GMR) sensors, Superconducting Quantum Interference Devices (SQUIDS), optical Faraday sensors, and pick-up coils, among other types of magnetic field sensors.

A structure formed of a magnetically permeable material, such as various types of aircraft, watercraft, and land-based vehicles (generically referred to as a surface herein) traveling in the presence of the Earth's B-field creates a magnetic signature, which can be detected via magnetic sensors. The magnetic measurements, such as made by B-field sensors, can be mathematically integrated to obtain a spatially integrated B-field value or ∫B·dl, for the area of the surface where the magnetic sensors are placed.

One B-field sensor is a tri-axial Flux Gate Magnetometer (3D-FGM). These 3D-FGM sensors have excellent sensitivity, down to approximately 10 nT, and are relatively low cost to fabricate; however, these types of B-field sensors often saturate above 100,000 nT, and thus are not useful above these ranges. Further, these discrete, permanently mounted, B-field sensors are adversely affected by the large spatial B-field gradients created by local anomalies and perturbations from a multitude of nearby magnetic sources and materials.

Existing spatial integration methods require many discrete 3D B-field sensors (e.g. 3D-FGMs) to spatially average these local magnetic perturbations. As the number of 3D B-field sensors increases to smooth out these localized magnetic perturbations, so too are the initial capital costs and installation costs associated with the many 3D B-field sensors and their associated wiring. Furthermore, operation and maintenance costs and complexity also increase as additional 3D B-field sensors are added, since each B-field sensor requires its own unique periodic re-calibration and correction from sensor drift.

Some systems also measure the magnetic field gradient (G) using a so-called gradiometer. A gradient field (G-field) is the change in the B-field strength with respect to a change in distance. In a one-dimensional cartesian coordinate system, the G-field (in T/m) is given by ΔB/Δx, where ΔB=Bⱼ−Bᵢ and the subscripts j and i refer to the j^{th} and i^{th} position of the B-field sensors.

A typical gradiometer includes two or more B-field sensors separated by a fixed distance Δx=xⱼ−xᵢ. During a gradiometer measurement, the simultaneous output from both B-field sensors is fed into a differential amplifier to obtain the value for ΔB. When the value from ΔB is divided by Δx, the value for the G-field can be obtained. Since the output from both B-field sensors is simultaneously measured and fed into the differential amplifier, values for both the magnitude of the G-field and its variation in time (dG/dt) can be obtained.

For the purposes of clarity, brevity, and enablement for this disclosure, the terms magnetic measurement device, magnetic sensor, B-field sensor, and magnetometer have the same general meaning and are used interchangeably to have the same meaning throughout this disclosure. The terms gradient magnetic sensor and gradiometer have the same general meaning and are used interchangeably throughout this disclosure to have the same meaning. Likewise, the terms gradient, ΔB/Δx, dB/dx, G-field have the same general meaning and are used interchangeably throughout this disclosure to have the same meaning.

What is needed, therefore, is a device that tends to reduce issues such as those described above, at least in part.

### SUMMARY

The above and other needs are met in a first aspect of the disclosure by a scanning spatially integrating magnetometer, having a drive motor and a guide mechanically coupled to the drive motor. A carriage is mechanically coupled to the guide, and the drive motor is adapted to provide motive power to translate the carriage along the guide. A B-field sensor is mechanically coupled to the carriage. A controller is in signal communication with the drive motor and the B-field sensor, and is adapted to receive signals from the B-field sensor and calculate an integrated B-field as the B-field sensor translates along the guide.

In some embodiments according to this aspect of the disclosure, the guide is at least one of flexible and rigid. In some embodiments, the B-field sensor is at least one of a Flux Gate Magnetometer, a Hall sensor, an NMR sensor, a Giant Magneto Resistance sensor, a SQUID sensor, and a pick-up coil.

According to another aspect of the disclosure, there is described a scanning spatially integrating gradiometer, with a drive motor and a guide mechanically coupled to the drive motor. A carriage is mechanically coupled to the guide, and the drive motor is adapted to provide motive power to translate the carriage along the guide. Two B-field sensors are mechanically coupled to the carriage, and spaced at a known distance one from another along an axis substantially parallel to the guide. A controller is in signal communication with the drive motor and the B-field sensors, and is adapted to receive signals from the B-field sensors and calculate an integrated B-field gradient as the B-field sensors translate along the guide.

In some embodiments according to this aspect of the disclosure, the guide is at least one of flexible and rigid. In some embodiments, the B-field sensors are at least one of a Flux Gate Magnetometer, a Hall sensor, an NMR sensor, a Giant Magneto Resistance sensor, a SQUID sensor, and a pick-up coil.

According to yet another aspect of the disclosure, there is described a spatially integrating optical magnetometer, with a polarized light source adapted to produce polarized light. An optical sensor is optically coupled to the polarized light source, and adapted to receive the polarized light from the polarized light source. A polarimeter is optically coupled to the optical sensor, and adapted to receive the polarized light from the optical sensor. The polarized light source, the optical sensor, and the polarimeter are adapted to measure a change in polarization angle of the polarized light as it propagates along the optical sensor.

In some embodiments according to this aspect of the disclosure, the optical sensor is at least one of a magnetic optic crystal cell, a Faraday cell, a flexible fiber optic cable, and a magnetically doped fiber optic cable. In some embodiments, the polarimeter is at least one of a Fiber Stokes Polarimeter, a rotating polarimeter, and a Bragg grating.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is an embodiment of a scanning spatially integrating magnetometer (s-SIM) device utilizing a scanning 3D B-field sensor such as a 3D-FGM.

FIG. 2 is an embodiment of a scanning Spatially integrating gradiometer (s-SIG) device utilizing at least two scanning 3D B-field sensors located a fixed distance apart.

FIG. 3 is an embodiment of a spatially integrating optical magnetometer (S-IOM) device.

FIG. 4 is an embodiment of the scanning system that is used to translate the B-field sensor or sensors.

FIG. 5 depicts a graphical and tabular representation of a methodology that can be used to compare multiple sensors directly and easily.

### DESCRIPTION

An s-SIM or s-SIG with only a single B-field sensor or a reduced number of B-field sensors, which detects the impact from the local anomaly B-fields, but also averages out the local anomaly effects over the length of the s-SIM or s-SIG, thereby reducing those effects, would be highly desirable. Discrete 3D B-field sensors do not have this capability and are left susceptible to local magnetic anomalies. For purposes of clarity, brevity, and enablement for the embodiments described in this disclosure, the term ∫B·dl is used to represent the spatially integrated output value of the s-SIM device and ∫G·dl is used to represent the output value of the s-SIG device.

### DEPICTED EMBODIMENTS

With reference now to the drawings, there are depicted all of the claimed elements of the various embodiments, although all claimed embodiments might not be depicted in a single drawing. Thus, it is appreciated that not all embodiments include all of the elements as depicted, and that some embodiments include different combinations of the depicted elements. It is further appreciated that the various elements can all have many different configurations, and are not limited to just the configuration of a given element as depicted. As indicated above, the elements of the drawings as depicted are not to scale, even with respect one to another, and relative size or thickness of one element cannot be determined by the aspect ratios of that element or with reference to any dimension of another element.

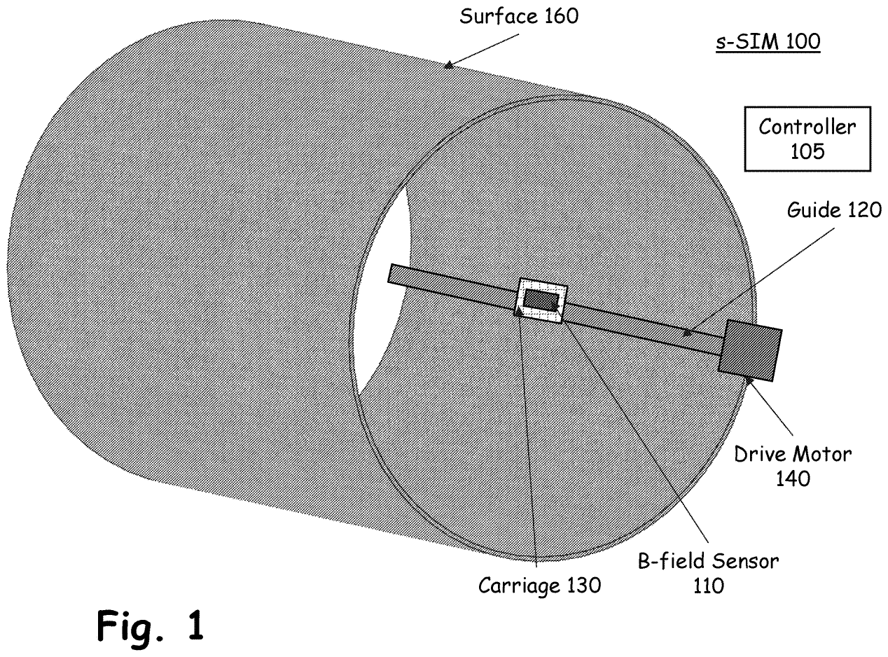

FIG. 1 depicts an embodiment of a scanning spatially integrating magnetometer (s-SIM) 100, including at least one B-field sensor 110, a guide 120, a carriage 130, a drive motor 140, and a controller 105. The B-field sensor 110 is mounted to the carriage 130 and the carriage 130 is mounted to the guide 120. The guide 120 can be at least one of flexible and rigid depending upon the application. The path shape of the guide 120 may be at least one of straight, curved, and helical, for example. The drive motor 140 translates the carriage 130 along with the B-field sensor 110 from one location on the guide 120 to the next. The controller 105 provides the control for the s-SIM 100.

The B-field measurements may be taken at at least one of fixed equally spaced distance intervals, variable distance intervals, and continuously, for example. The drive motor 140 can translate the carriage 130 in the forward direction or the reverse direction. The guide 120 can be mounted at least one of directly and indirectly to a hull, shell, or other surface 160, and at least one of interior of the surface 160 and exterior of the surface 160.

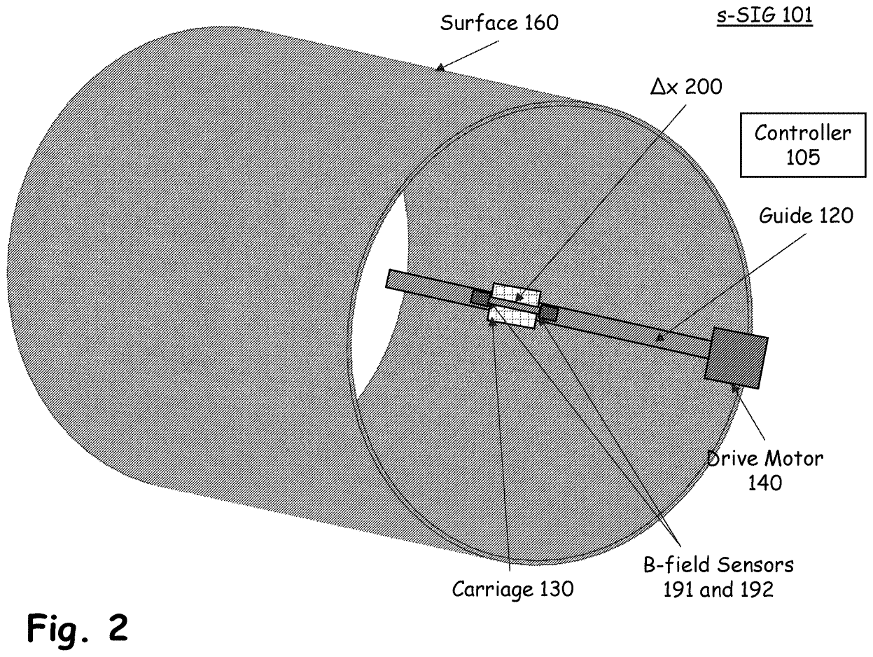

FIG. 2 depicts an embodiment of the scanning spatially integrating gradiometer (s-SIG) 101, including at least two B-field sensors 191, 192, a guide 120, a carriage 130, a drive motor 140, and a controller 105. The twin B-field sensors 191, 192 are mounted to the carriage 130 at a known fixed distance Δx=xⱼ−xᵢ 200 apart. The twin B-field sensors 191, 192 are mounted to the carriage 130, and the carriage 130 is mounted to the guide 120. The guide 120 can be at least one of flexible and rigid, depending upon the application. The path shape of the guide 120 may be at least one of straight, curved, and helical, for example. The controller 105 provides the control for the s-SIG device 101. A drive motor 140 translates the carriage 130 along with the at least two B-field sensors 191, 192 from one location on the guide 120 to its next. The drive motor 140 can translate the carriage 130 in the forward direction or the reverse direction.

The magnitude of the G-field is obtained from the differential output of the twin B-field sensors 191, 192 divided by the spatial distance 200 between the twin B-field sensors 191, 192. The guide 120 can be mounted at least one of directly and indirectly to a surface 160, and at least one of interior of the surface 160 and exterior of the surface 160.

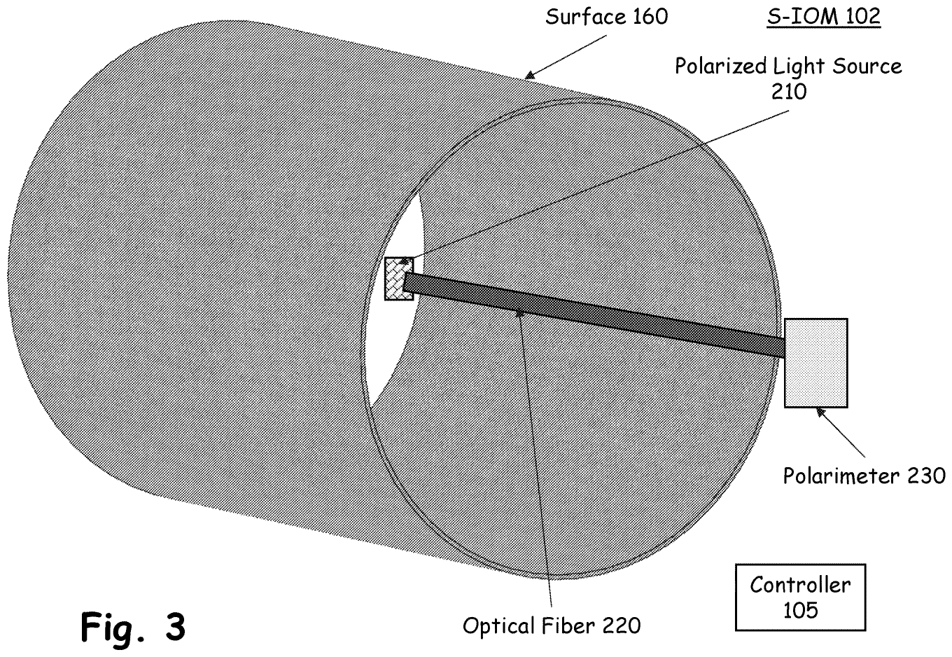

FIG. 3 depicts an embodiment of a spatially integrating optical magnetometer (S-IOM) 102, including a polarized light source 210, an optical fiber 220, a polarimeter 230 that contains a phase sensitive detector and a light sensitive detector, and a controller 105. When polarized light is emitted from the light source 210 and launched into the optical fiber 220, the polarization vector of the light in the optical fiber 220 is rotated by an angle 40 when in the presence of a B-field. The phase sensitive detector and the light sensitive detector contained within the polarimeter 230 measure the change in the polarization vector, and from Eq. (1) (hereinbelow), the B-field can be determined. The optical fiber 220 may be disposed in at least one of inside and outside the surface 160 and can be oriented however needed for the desired measurement. The optical fiber 220 can be formed of at least one of flexible and rigid crystal. Some optical fiber media 220 for the S-IOM device 102 have large Verdet coefficients.

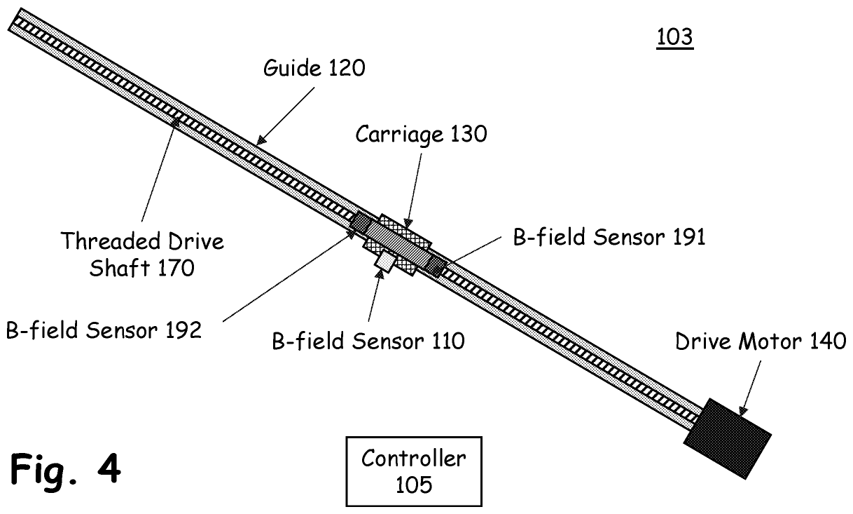

FIG. 4 depicts an embodiment 103 with a single B-field sensor 110 (like the s-SIM 100) and two B-field sensors 191, 192 (like the s-SIG 101) all mounted to a single carriage 130, which is mounted to the guide 120 and driven by a drive motor 140 and a threaded drive shaft 170.

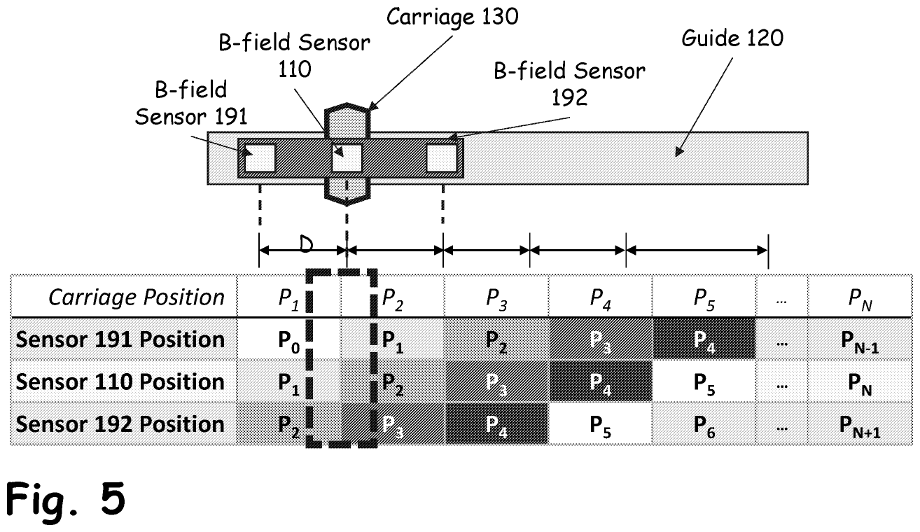

FIG. 5 depicts a graphical and tabular representation of the methodology that can be used to facilitate a direct comparison of the single B-field sensor 110 of the s-SIM 100 with the twin B-field sensors 191, 192 of the s-SIG 101, in an embodiment such as that depicted in FIG. 4. In this embodiment, three B-field sensors 110, 191, 192 are mounted to a carriage 130, which is mounted to a guide 120. In this simplified example, the three B-field sensors 110, 191, 192 are all mounted on the same carriage 130 and guide 120, but they could also be on different carriages 130 or guides 120 as desired. The three B-field sensors 110, 191, 192 may or may not be of the same type. The table shows a simplified example of how the readings may be directly compared during a scan of the combined s-SIM 100 and s-SIG 101 embodiment of FIG. 4.

In FIG. 5, the carriage 130 is located at position 2 [P₂]; at this location, the single B-field sensor 110 and the twin B-field sensors 191, 192 are each in different physical locations. B-field sensor 191 (the leftmost sensor) is in position 1 [P₁], B-field sensor 110 (the middle sensor) is in position 2, and B-field sensor 192 (the rightmost sensor) is in position 3 [P₃]. Note that since the three sensors 110, 191, 192 are in physically different locations, the readings cannot be directly compared unless the B-field is uniform. However, when the carriage 130 is in position 1, B-field sensor 192 is located in position 2. Likewise, when the carriage 130 is located in position 3, B-field sensor 191 is located in position 2. A given sensor's physical location is a function of the carriage 130 position, and may be offset from a different sensor's location. When individual B-field sensors 110, 191, 192 are in the same physical location, their readings may be directly compared, even if that means the carriage 130 is in different locations at the time of the readings.

### Further Details

For the embodiments in this disclosure, various configurations of B-field measurement sensors 110, 191, 192 and B-field measurement techniques are described for measuring the B-field and ultimately obtaining the value for ∫B·dl: 1) scanning a 3D B-field sensor (s-3D-FGM) and 2) a spatially integrating optical magnetometer (S-IOM). However, it should be understood by one skilled in the art that other B-field measurement sensors and other B-field techniques are possible to obtain the values for ∫B·dl and ∫G·dl, and no limitation on the types of B-field sensor or B-field measurement system is expressed nor should be implied.

### Scanning Tri-Axial Magnetometer (S-SIM)

In one embodiment, the s-SIM 100 includes a scanning triaxial magnetometer. For the s-SIM 100 embodiment described in this disclosure, the s-SIM 100 device includes five primary components: (1) at least one B-field sensor 110, (2) at least one carriage 130, (3) at least one guide 120, (4) at least one motor 140 that drives the B-field sensor 110 from one location on the guide 120 to the next, and (5) the measurement electronics (controller 105) that supply at least one of electrical power and control signals to the drive motor 140 and the B-field sensors, and subsequently measure and convert the sensor 110 signals to corresponding vector components of B-field, i.e. Bₓ, B_{y}, B_{z}.

The scanning system 120, 130, 140 is the mechanism that physically translates the B-field sensors 110 from one location to the next. The scanning system 120, 130, 140 includes a guide 120 that is at least one of rigid and flexible, to which the B-field sensors 110 are attached, and a motor 140 which is used to translate the B-field sensors 110 along the guide 120. There are a plethora of types of scanning systems 120, 130, 140 that could be implemented, including but not limited to a stepper motor with encoder, a linear motor with a threaded drive shaft, a reel-to-reel translation, and other types of motion scanning systems. A linear motor 140 with a threaded drive shaft 170 is shown in FIGS. 1-4. However, it should be understood by one skilled in the art that other types of scanning systems are available, and no limitation on the type of scanning system is expressed, nor should be implied.

The scanning system 120, 130, 140 can be driven manually or by a motor 140. Some common types of motors 140 include but are not limited to electric motors, pneumatic motors, hydraulic motors, wax motors, among other types of motors. It is important that if an electric motor is used in scanning the B-field sensor 110, it does not electrically interfere with the B-field measurement itself, thereby distorting the measured values of B-field and producing inaccurate results.

To avoid this from occurring, the motor 140 can be shielded with magnetic permeable materials such as mu-metal or steel. This can also be avoided simply by turning the scanning motor 140 off during the B-field measurement, and only activating the motor 140 long enough to move the B-field sensor 110 to its next location, and then once again turning off the electric motor 140 prior to making the next B-field measurement. This process of turning off the electric motor 140 prior to measurement can be repeated for each discrete measurement location.

The distance between discrete measurement points can be large for a coarse scan or very short for a finer scan, depending upon the requirements of the application. The distance between discrete measurements points can be a uniform fixed distance or it can be variable distance between points, or a combination of both fixed and variable distances.

The B-field measurement scan can also be made in a continuous manner without stopping at discrete locations. To obtain the most accurate B-field values during a continuous-type measurement scan, it is important that the B-field measurements are made faster than the expected time variation of the B-field, and that a motor drive 140 is chosen that does not interfere with the B-field measurement itself.

For this embodiment, the B-field measurement scan can be performed in both the positive (or forward) direction and then reversed and performed in the opposite (or reverse) direction at the same or different points of measurement. However, performing both forward and reverse B-field scans at the same locations helps determine measurement repeatability and consistency.

A common type of B-field sensor 110 for this embodiment is at least one or more 3D-FGMs, although other types of B-field sensors 110 may be used, such as Hall or NMR sensors. The 3D feature allows for measurements of the B-field along all three of its vector axes at each location. The vector components of the B-field (i.e. B_{A}, B_{V}, B_{L}) at each discrete location can then be mathematically integrated to determine ∫Bᵢ·dl. The scanning system provides a means for scanning control of the B-field sensors 110 mounted to the carriage 130 while exposed to the total B-field from all its sources, which may include, but is not limited to, the Earth's B-field, the magnetization of the surface 160, and local magnetic anomalies, for example.

The advantage of the embodiments described in this disclosure over the prior art is that the scanning feature enables the use of only a single or reduced number of B-field sensors 110 instead of multiple, discrete FGMs permanently installed on the surface 160. The ∫B·dl value is obtained by physically translating the at least one of the B-field sensors 110, 191, 192 rather than permanently locating multiple B-field sensors along the surface 160. For the embodiments described in this disclosure, it is the scanning system's guide 120 that can be permanently attached to the surface 160 and not the B-field sensor 110 itself, as the B-field sensor 110 is allowed to be translated along the guide 120. Thus, an accurate value for at least one of ∫B·dl and ∫G·dl can be obtained using a single 3D B-field sensor 110, 191, 192.

### Scanning Tri-Axial Flug Gate Gradiometer (S-3D-FGG)

In one embodiment, the s-SIG 101 device is comprised of a scanning G-field sensor 191, 192 that is translated in space from one measurement point and then to its next measurement location. The distance between measurement points can be large for a coarse scan or very small for a finer scan depending upon the requirements of the application. The discrete distance between measurement points can be uniform and fixed, variable, or a combination of both fixed and variable. The G-field measurement scan can also be made in a continuous manner without stopping at discrete fixed locations. For more accurate measurements of the G-field when using a continuous measurement scan, it is preferred that the G-field measurements are made faster than the time variation of the G-field.

For this embodiment, the G-field measurement scan can be performed in both the positive direction and then reversed and performed in the opposite direction at the same (or different) points to determine repeatability and consistency between the forward and reverse scans. A common type of G-field sensor (or gradiometer) for this embodiment is at least two 3D-FGMs 191, 192 located at a fixed distance (Δx) apart, one from another, in which the G-field is determined by simultaneous measuring the two B-field sensors 191, 192 and feeding the output of the two B-field sensors 191, 192 into a differential amplifier. The output from the differential amplifier (ΔB=Bⱼ−Bᵢ) divided by the fixed distance (Δx=xⱼ−xᵢ) between the two sensors 191, 192 determines the G-field. The 3D feature allows for measurements of the B-field along all three of the vector axes at each location.

In another embodiment, the s-SIG device 101 is comprised of only a single B-field sensor 110; however, by translating the single B-field sensor 110 (e.g. 3D-FGM) from one location to the next (e.g. Δx=xⱼ−xᵢ) and making a measurement of the B-field vector components at both spatial locations i,j, the value for the G-field can be obtained by the mathematical operation ΔB/Δx=Bⱼ−Bᵢ/xⱼ−xᵢ). This mathematical value of the G-field taken from a single B-field sensor 110 and translated in space by the scanning system 120, 130, 140 described in this disclosure can be compared to a measurement of an actual gradiometer device possessing two B-field sensors 191, 192 so long as the spatial distance Δx is the same and the two locations in space (j, i) are the same.

The methodology of comparing the gradiometer measurement of the G-field to the translated single magnetometer is shown in FIG. 5. This comparison of the G-field between the two measurement devices (s-SIM 100 vs. s-SIG 101) can only be performed for static B-fields, and is not valid for time varying B-fields dB/dt.

Thus, for the embodiments described in this disclosure it is sometimes advantageous to mount both a magnetometer (i.e. one B-field sensor 110) and a gradiometer (two B-field sensors 191, 192 with a differential output) on the same scanning platform 130, such as depicted in FIG. 4, so that checks on the consistency and the repeatability of the system can be performed, thereby enabling enhanced accuracy of measurements. In yet another embodiment, a magnetometer with one B-field sensor 110, and a gradiometer with two B-field sensors 191, 192 are on the same scanning platform 130, such as depicted in FIG. 4, and placed alongside an optical fiber 220 with accompanying polarized light source 210 and polarimeter 230, so that the readings of all three of an s-SIM 100, s-SIG 101, and S-IOM 102 can be compared, one to another.

### Spatially Integrating Optical Magnetometer (S-IOM)

Another type of system described in this disclosure is an S-IOM 102. An S-IOM 102 produces an output value of ∫B·dl (in T−m), and hence does not need to be scanned (i.e. translated in space) or subsequently mathematically integrated to obtain a value for ∫B·dl.

Without being bound by theory, a discussion of the mechanism of S-IOM 102 is next provided for clarity and enablement of the embodiment. For the embodiment described in this disclosure, the S-IOM 102 is based upon the so-called Faraday effect in which plane or circularly polarized light is rotated by an angle (ΔΘ) in the presence of a static B-field, where ΔΘ=Θ_{f}−Θ_{I} is the measured change in the polarization angle from its initial value (Θᵢ) exiting the polarized light source to its final value (Θ_{f}) after traversing the B-field via the optical sensor. When the lines of magnetic flux are parallel to the propagation direction of the light, this is known as the Faraday Effect. When the lines of magnetic flux are perpendicular to the propagation direction of the light, this is known as the Voight effect. The amount of angular rotation ΔΘ(in degrees) that the incident light experiences from its initial polarization is given by:

ΔΘ=C_{F,V}(T,B,λ)*L*B (1)
where C_{F,V} (T, B, λ) are the temperature, magnetic field, and wavelength dependent Verdet coefficients, L is the optical path length, and B is the magnetic flux density in Tesla. The values for the Verdet Coefficient can be approximated by the expression:ⁱ

C_{F,V}(T,B,λ)~π*γ/(n*λ) (2)
where γ is the magneto-gyration coefficient, n is the index of refraction of the optical medium, and λ is the wavelength of light propagating in the medium. The magneto-gyration coefficient (γ) is a measure of how strongly the electrons are curved in the external B-field when they are propagated by the electric field of the light. Hence, lower wavelengths and index of refractions (n) translate to higher Verdet Coefficients and hence enhanced measurement sensitivities. The Verdet coefficients (C_{F}) are significantly larger for magnetic lines of flux parallel to the direction of propagation (Faraday effect) than for magnetic flux lines perpendicular to the direction of propagation i.e. the Voight effect (Cᵥ).

An S-IOM 102 as depicted in FIG. 3 includes four primary components: (1) at least one polarized light source 210, (2) at least one optical sensor or optical medium 220, (3) and at least one polarimeter 230, and (4) a controller 105. For the purposes of clarity, brevity, and enablement for the embodiment described in this disclosure, a polarimeter 230 is a device that measures the change in polarization angle ΔΘ from its incident value Θᵢ to its final value Θ_{f}. For the S-IOM 102 embodiment described in this disclosure, there are a plethora of methods to measure the change in polarization angle ΔΘ including but not limited to a Fiber Stokes Polarimeter (FSP), Photo Elastic Modulators, rotating polarimeter, fiber Bragg Grating polarimeter, among other types of polarimeters.

In one embodiment, the S-IOM 102 utilizes an optical fiber as the optical sensor 220. The optical fiber sensor 220 is optically coupled to the polarized light source 210 on one end and the polarimeter 230 on its other end. The optical fiber sensor 220 can either be a single mode (SM) or multi-mode (MM) optical fiber. Some common types of optical fiber sensors 220 include but are not limited to flint glass (i.e. Pb doped glass), Zblan Fluoride Glass (ZFG), Germanium oxide Glass (GeG), Indium Fluoride Glass (IFG), Rare earth-doped glass, and other types of magnetically sensitive optical fibers. One common characteristic of optical fiber sensors 220 is that they have relatively large Verdet coefficients and hence large angular rotations in ΔΘ the presence of applied B-fields.

In another embodiment, the S-IOM 102 utilizes a Faraday cell. A Faraday cell includes an optical crystal that has a large Verdet coefficient, i.e. polarized light rotates by an angle ΔΘ in the presence of a B-field. Shorter, more compact Faraday cells are used in confined space applications where the propagation of polarized light over long length optical fibers is not needed. Some common types of magnetically sensitive optical crystals include but are not limited to Terbium-Gallium-Garnet crystals (TGG), terbium-doped borosilicate glass, and Yttrium-Iron-Garnet (YIG), and other types of high Verdet optical crystals.

An advantage for the longer length high Verdet optical fibers 220 over the shorter length high Verdet optical crystals is that in a uniform B-field, the total angular rotation ΔΘ increases linearly with the optical path length (L) of the fiber, thereby making the measurement more sensitive as the fiber length increases. In addition, some optical fibers 220 like GeG, for example, are quite rugged and flexible, and can conform to the complex shapes and contours of the surface 160. This ruggedness and mechanical flexibility may be useful in other applications as well.

As used herein, the phrase “at least one of A, B, and C” means all possible combinations of none or multiple instances of each of A, B, and C, but at least one A, or one B, or one C. For example, and without limitation: A×1, A×2+B×1, C×2, A×1+B×1+C×1, A×7+B×12+C×113. It does not mean A×0+B×0+C×0.

The foregoing description of embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

### DEFINITIONS

The terms, acronyms, and explanations listed below are provided for convenience and are not to be taken as binding for claim construction.

| Symbol | Definition | Units (if applicable) |
|---|---|---|
| AC | Alternating Current | Root mean squared current |
| | | in Amperes (Arms) |
| B or B-field | Magnetic field | Tesla |
| Bₓ or B_{A} | Athwart component of | T |
| | B-field | |
| B_{y} or B_{V} | Vertical component of | T |
| | B-field | |
| B_{z} or B_{L} | Longitudinal component | T |
| | of B-field | |
| ∫B · dl | Integrated B-field | Tesla-meters |
| Cu | Copper | |
| DC | Direct Current | A |
| FGM | Flux Gate Magnetometer | |
| 3D-FGM | Triaxial Flux Gate | |
| | Magnetometer | |
| s-3D-FGM | Scanning Triaxial Flux | |
| | Gate Magnetometer | |
| FSP | Fiber Stokes Polarimeter | |
| G or G-field | Gradient field | Tesla/meters |
| ∫G · dl | Integrated gradient field | T |
| GMR | Giant Magneto Resistance | |
| HEP | High Energy Physics | |
| I | Current | Amps |
| M | Magnetization | Amps/meters |
| MM | Multi-mode optical fiber | |
| MRI | Magnetic Resonance | |
| | Imaging | |
| NMR | Nuclear Magnetic | |
| | Resonance | |
| NP | Nuclear Physics | |
| Pb | Lead | |
| μᵣ | Relative magnetic | dimensionless quantity |
| | permeability | |
| μ₀ | Magnetic permeability of | (N/A²) |
| | free space | |
| SIG | Spatially Integrating | |
| | Gradiometer | |
| SIM | Spatially Integrating | |
| | Magnetometer | |
| S-IOM | Spatially Integrating | |
| | Optical Magnetometer | |
| SM | Single Mode optical fiber | |
| SQUID | Superconducting Quantum | |
| | Interference Device | |
| V | Volume | m³ |

1. A scanning spatially integrating magnetometer, comprising:
a drive motor,
a guide mechanically coupled to the drive motor,
a carriage mechanically coupled to the guide, wherein the drive motor is adapted to provide motive power to translate the carriage along the guide,
a B-field sensor mechanically coupled to the carriage, and
a controller in signal communication with the drive motor and the B-field sensor, and adapted to receive signals from the B-field sensor and calculate an integrated B-field as the B-field sensor translates along the guide.

2. The scanning spatially integrating magnetometer of claim 1, wherein the guide is at least one of flexible and rigid.

3. The scanning spatially integrating magnetometer of claim 1, wherein the B-field sensor is at least one of a Flux Gate Magnetometer, a Hall sensor, an NMR sensor, a Giant Magneto Resistance sensor, a SQUID sensor, and a pick-up coil.

4. A scanning spatially integrating gradiometer, comprising:
a drive motor,
a guide mechanically coupled to the drive motor,
a carriage mechanically coupled to the guide, wherein the drive motor is adapted to provide motive power to translate the carriage along the guide,
two B-field sensors mechanically coupled to the carriage and spaced at a known distance one from another along an axis substantially parallel to the guide, and
a controller in signal communication with the drive motor and the B-field sensors, and adapted to receive signals from the B-field sensors and calculate an integrated B-field gradient as the B-field sensors translate along the guide.

5. The scanning spatially integrating magnetometer of claim 4, wherein the guide is at least one of flexible and rigid.

6. The scanning spatially integrating magnetometer of claim 4, wherein the B-field sensors are at least one of a Flux Gate Magnetometer, a Hall sensor, an NMR sensor, a Giant Magneto Resistance sensor, a SQUID sensor, and a pick-up coil.

7. A spatially integrating optical magnetometer, comprising:
a polarized light source adapted to produce polarized light,
an optical sensor optically coupled to the polarized light source, and adapted to receive the polarized light from the polarized light source, and
a polarimeter optically coupled to the optical sensor, and adapted to receive the polarized light from the optical sensor,
wherein the polarized light source, the optical sensor, and the polarimeter are adapted to measure a change in polarization angle of the polarized light as it propagates along the optical sensor.

8. The spatially integrating optical magnetometer of claim 7, wherein the optical sensor is at least one of a magnetic optic crystal cell, a Faraday cell, a flexible fiber optic cable, and a magnetically doped fiber optic cable.

9. The spatially integrating optical magnetometer of claim 7, wherein the polarimeter is at least one of a Fiber Stokes Polarimeter, a rotating polarimeter, and a Bragg grating.
